(19) United States
(12) Patent Application Publication
(10) Pub. No.: US 2007/0187687 A1
(43) Pub. Date: Aug. 16, 2007

(54) Pixel structure and liquid crystal display panel

(76) Inventors: Meng-Chi Liou, Taoyuan City (TW); Yuan-Hao Chang, Taipei City (TW)

Correspondence Address: J.C. Patents, Inc., Suite 250, 4 Venture, Irvine, CA, 92618, US

(21) Appl. No.: 11/355,605

(22) Filed: Feb. 15, 2006

(51) Int. Cl. H01L 29/04

(52) U.S. Cl. 257/72

(57) ABSTRACT

A pixel structure including a scan line, a data line, a first thin film transistor, a second thin film transistor, a first pixel electrode and a second pixel electrode, is described. The first thin film transistor is electrically connected to the scan line and the data line and has a first device width/length ratio. The second thin film transistor is also electrically connected to the scan line and the data line and has a second device width/length ratio. The first pixel electrode is electrically connected to the first thin film transistor while the second pixel electrode is electrically connected to the second thin film transistor.

### BACKGROUND OF THE INVENTION

1. Field of Invention

The present invention relates to a pixel structure and liquid crystal display panel with the pixel structure. More particularly, the present invention relates to a liquid crystal display panel and pixel structure thereof, which can reduce the color shift.

2. Description of Related Art

The thin film transistor liquid crystal display (TFT-LCD), with such advantages as high imagine quality, high space utilization efficiency, low power consumption, no radiation, etc., has become the major display product in the market. At present, the market demand for LCD is leaning towards high contrast ratio, quick response and wide-angle view, etc. The current technologies which can achieve the wide-angle view requirement include, for example, TFT-LCD with multi-domain vertically alignment (MVA), TFT-LCD with multi-domain horizontal alignment (MHA), etc.

Although the TFT-LCD with MVA or MHA can achieve wide-angle view, the color shift is the drawback. The so-called color shift means that users will see different color scale images when viewing the image displayed on the display from different view angles. For example, users may see white shift image when viewing from a slant angle.

At present, solutions to resolve the above problem of color shift have been proposed, wherein one of the methods is to form two types of liquid crystal capacitors in single pixel structure, so that the different liquid crystal capacitors may generate different arrangements of liquid crystal molecule in a single pixel structure. Although the method can improve the color shift, some disadvantages such as insufficient final brightness and low contrast still exist.

Another method is to form two scan lines, two transistors, and two independent storage capacitors in a single pixel structure, so that different liquid crystal molecule arrangements may be generated in a single pixel structure due to the different capacitances of the two storage capacitors. Although the method can resolve the problem of color shift and prevent insufficient final brightness, as it needs to form two scan lines, two transistors, and two independent storage capacitors in a single pixel structure, a suitable driving circuit must be additionally made, and the opening ratio may be reduced.

### SUMMARY OF THE INVENTION

Accordingly, the present invention is directed to provide a pixel structure, and the liquid crystal display panel using the pixel structure can reduce color shift.

Another objective of the present invention is to provide a liquid crystal display panel, which not only can resolve the problem of color shift, but also can avoid the problems such as insufficient final brightness, low contrast, and the reduction of the opening ratio.

In order to achieve the above or other aspects of the present invention, the present invention provides a pixel structure, including a scan line, a data line, a first thin film transistor, a second thin film transistor, a first pixel electrode and a second pixel electrode. The first thin film transistor is electrically connected to the scan line and the data line and has a first device width/length ratio. The second thin film transistor is also electrically connected to the scan line and the data line and has a second device width/length ratio. In addition, the first pixel electrode is electrically connected to the first thin film transistor while the second pixel electrode is electrically connected to the second thin film transistor.

In one embodiment of the present invention, the first device width/length ratio of the first thin film transistor is greater than the second device width/length ratio of the second thin film transistor.

In one embodiment of the present invention, the first pixel electrode and the second pixel electrode further include an alignment slit pattern. In one embodiment, the alignment slit pattern includes a plurality of slits parallel to the scan line.

In one embodiment of the present invention, the pixel structure further includes an alignment protrusion pattern, disposed on the first pixel electrode and the second pixel electrode.

In one embodiment of the present invention, the pixel structure further includes a storage capacitor, disposed under the first pixel electrode and the second pixel electrode.

In one embodiment of the present invention, the first pixel electrode and the second pixel electrode are transparent electrodes, reflective electrodes, or one of them is a reflective electrode and the other is a transparent electrode.

The present invention also provides a liquid crystal display panel, including a thin film transistor array substrate; a color filter substrate, disposed opposite to the thin film transistor array substrate; and a liquid crystal layer, disposed between the thin film transistor array substrate and the color filter substrate. The thin film transistor array substrate has a plurality of pixel structures, in particular, each pixel structure includes a scan line, a data line, a first thin film transistor, a second thin film transistor, a first pixel electrode and a second pixel electrode. The first thin film transistor is electrically connected to the scan line and the data line and has a first device width/length ratio. The second thin film transistor is also electrically connected to the scan line and the data line and has a second device width/length ratio. In addition, the first pixel electrode is electrically connected to the first thin film transistor while the second pixel electrode is electrically connected to the second thin film transistor.

In one embodiment of the present invention, the first device width/length ratio of the first thin film transistor of each pixel structure is greater than the second device width/length ratio of the second thin film transistor.

In one embodiment of the present invention, the first pixel electrode and the second pixel electrode of each pixel structure further include an alignment slit pattern. Moreover, an alignment protrusion pattern is further included and disposed on the color filter array substrate. In another embodiment of the present invention, the alignment slit pattern includes a plurality of slits parallel to the scan line.

In one embodiment of the present invention, the thin film transistor array substrate further includes an alignment protrusion pattern, disposed on the first pixel electrode and the second pixel electrode. In addition, an alignment slit pattern is further included and disposed on the color filter array substrate.

In one embodiment of the present invention, each pixel structure further includes a storage capacitor, disposed under the first pixel electrode and the second pixel electrode.

In one embodiment of the present invention, the first pixel electrode and the second pixel electrode of each pixel structure are transparent electrodes, reflective electrodes, or one of them is a reflective electrode and the other is a transparent electrode.

In one embodiment of the present invention, the color filter array substrate includes a black matrix and a color filter layer.

In present invention, two thin film transistors with different device width/length ratios are disposed in a single pixel structure, and the two thin film transistors are electrically connected to the same scan line and data line. When the two thin film transistors are driven by the scan line and the data line, two different pixel electrode voltages are generated in the two electrically connected pixel electrodes, respectively, so that the liquid crystal molecule within the single pixel structure may generate different arrangements of liquid crystal molecule. Accordingly, the problem of color shift can be resolved.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a pixel structure according to one preferred embodiment of the present invention.

FIG. 2 is a cross-sectional schematic view of FIG. 1 along line I-I′.

FIG. 3 is a schematic top view of a pixel structure according to another preferred embodiment of the present invention.

FIG. 4 is a cross-sectional schematic view of a liquid crystal display panel according to one preferred embodiment of the present invention.

FIG. 5 is a cross-sectional schematic view of a liquid crystal display panel according to another preferred embodiment of the present invention.

### DESCRIPTION OF EMBODIMENTS

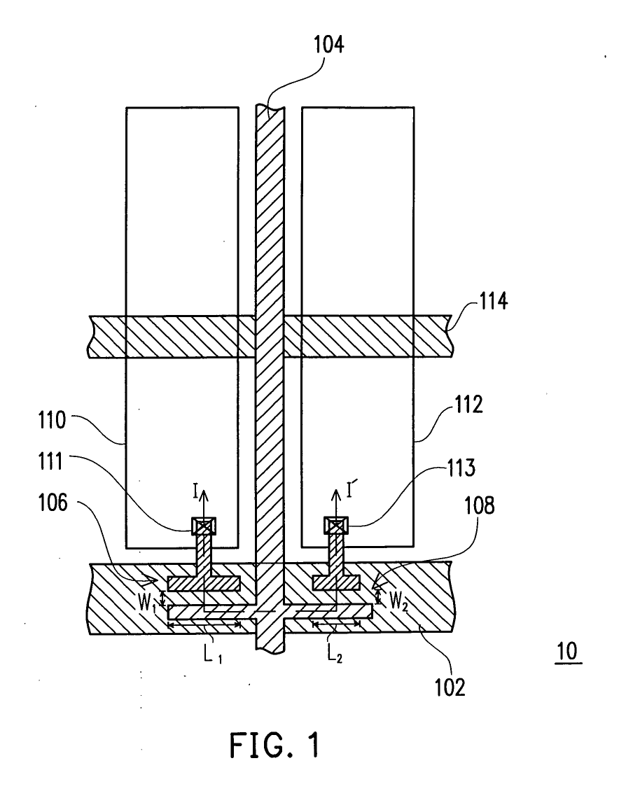

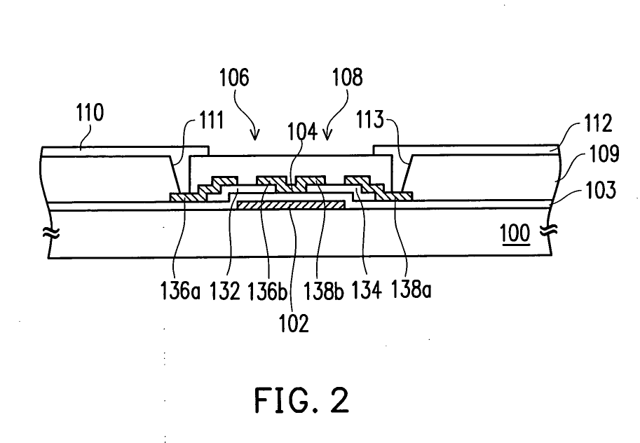

FIG. 1 is a schematic top view of a pixel structure according to one preferred embodiment of the present invention. FIG. 2 is a cross-sectional schematic view of FIG. 1 along line I-I′. Referring to FIG. 1 and FIG. 2 simultaneously, the pixel structure 10 of the present invention includes a scan line 102, a data line 104, a first thin film transistor 106, a second thin film transistor 108, a first pixel electrode 110 and a second pixel electrode 112.

The scan line 102 and the data line 104 are disposed on the substrate 100 and electrically connected to the first thin film transistor 106 and the second thin film transistor 108. The first thin film transistor 106 includes a gate (a part of the scan line 102); a gate insulation layer 103 covering the gate, a channel layer 132 disposed on the gate insulation layer 103; and a drain 136a and a source 136b, disposed on the channel layer 132. The second thin film transistor 108 includes a gate (i.e., a part of the scan line 102); a gate insulation layer 103 covering the gate, a channel layer 134 disposed on the gate insulation layer 103; and a drain 138a and a source 138b, disposed on the channel layer 134.

Therefore, both of the first thin film transistor 106 and the second thin film transistor 108 are formed on the scan line 102, and part of the scan line 102 serves as the gates. Both of the source 136b of the first thin film transistor 106 and the source 138b of the second thin film transistor 108 are connected to the data line 104. Therefore, the thin film transistors 106, 108 are electrically connected to the same scan line 102 and the same data line 104.

In particular, the first thin film transistor 106 has a first device width/length ratio, and the second thin film transistor 108 has a second device width/length ratio. In one preferred embodiment, the first device width/length ratio of the first thin film transistor 106 is greater than the second device width/length ratio of the second thin film transistor 108. In more detail, the device length of the first thin film transistor 106 is L1 and the device width is W1, while the device length of the second thin film transistor 108 is L2 and the device width is W2. The first device width/length ratio (W1/L1) is greater than the second device width/length ratio (W2/L2). Moreover, a protection layer 109 covering on the first thin film transistor 106 and the second thin film transistor 108 is further provided. The first pixel electrode 110 and the second pixel electrode 112 are formed on the surface of the protection layer 109. The first pixel electrode 110 is electrically connected to the first thin film transistor 106. For example, the first pixel electrode 110 and the first thin film transistor 106 are electrically connected to each other through the contact window 111. The second pixel electrode 112 is electrically connected to the second thin film transistor 108. For example, the second pixel electrode 112 and the second thin film transistor 108 are electrically connected to each other through the contact window 113. In one embodiment, the first pixel electrode 110 and the second pixel electrode 112 are disposed on the two sides of the data line 104, respectively, and the two pixel electrodes 110, 112 are separated from each other. The first pixel electrode 110 and the second pixel electrode 112 are, for example, transparent electrodes, respectively. Of course, the present invention does not limit that the two pixel electrodes 110, 112 must be transparent electrodes. Also, the two pixel electrodes 110, 112 can also be reflective electrodes, or one of them is a transparent electrode and the other is a reflective electrode.

According to one preferred embodiment of the present invention, the pixel structure 10 further includes a common electrode 114, disposed under the first pixel electrode 110 and the second pixel electrode 112, wherein the common electrode 114 and the first pixel electrode 110, the second pixel electrode 112 may respectively create capacitance coupling as the storage capacitance of the pixel structure 10. In particular, as there is different device width/length ratios of the first thin film transistor 106 and the second thin film transistor 108, when the pixel structure 10 is driven by the scan line 102 and the data line 104, the voltages input into the first pixel electrode 110 and the second pixel electrode 112 may be different. Therefore, as there is the different device width/length ratios of the first thin film transistor 106 and the second thin film transistor 108 in the present invention, two pixel electrode voltages may be generated in a single pixel structure 10 when driven by the same scan line 102 and data line 104.

When the pixel structure is applied in the liquid crystal display panel, the liquid molecules disposed above the first pixel electrode 110 and the liquid molecules disposed above the pixel electrode 112 have different, arrangements. Therefore, the liquid molecules in single pixel structure 10 of the present invention can have two different arrangements. Accordingly, the color shift of liquid crystal display panel can be resolved.

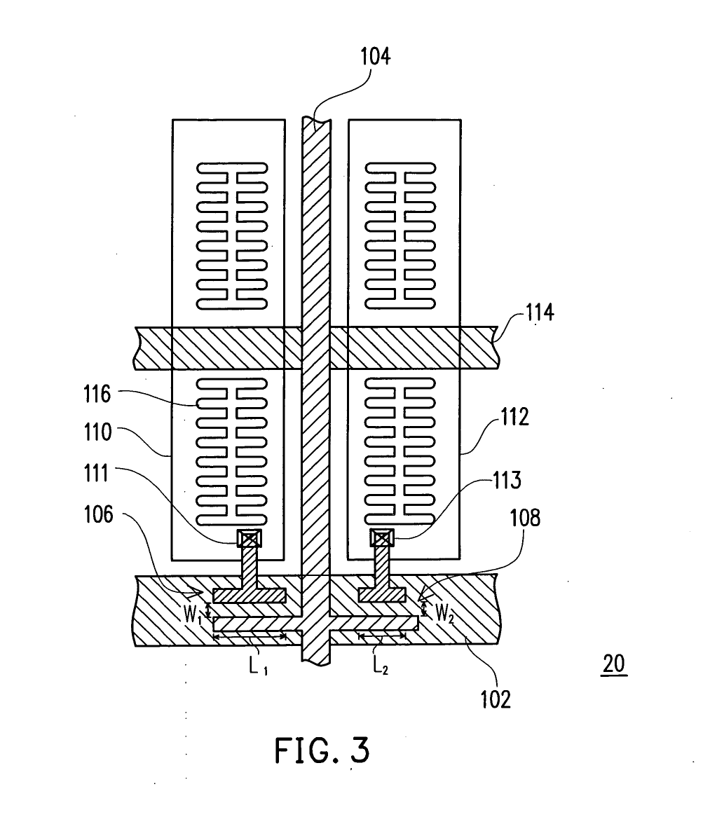

FIG. 3 is a schematic top view of a pixel structure according to another embodiment of the present invention. The pixel structure shown in FIG. 3 is a pixel structure 20 applied in wide-angle view liquid crystal display panel, which is similar to the pixel structure 10 shown in FIG. 1, and the difference is that an alignment slit pattern 116 is formed in both of the first pixel electrode 110 and the second pixel electrode 112. The alignment slit pattern 116 shown in FIG. 3 is a multi-domain horizontal alignment (MHA), which is composed of, for example, a plurality of slits parallel to the scan line 102. However, the present invention does not limit the alignment format and figure of the alignment slit pattern 116, and the alignment slit pattern 116 can also be multi-domain vertical alignment (MVA) pattern, or other alignment patterns.

If the pixel structure 20 of the present invention is applied in a liquid crystal display panel, not only the wide-angle objective can be achieved, but the color shift in the conventional wide-angle view liquid crystal display panel can be prevented. Moreover, as the present invention makes use of the difference device width/length ratios of the thin film transistors, a single pixel structure has different pixel electrode voltages, and this mode does not result in insufficient final brightness and low contrast. In addition, as the single pixel of the present invention includes only a data line, a scan line, and a capacitor electrode, there's no difference between the design of the driving circuit of the present invention and the design of the driving circuit of the common pixel structures, therefore no additional design for special driving circuit is needed. Moreover, as the single pixel structure includes only a data line, a scan line, and a capacitance electrode, the opening ratio may not be reduced substantially.

The following is a description of the above pixel structure applied in the liquid crystal display panel in detail.

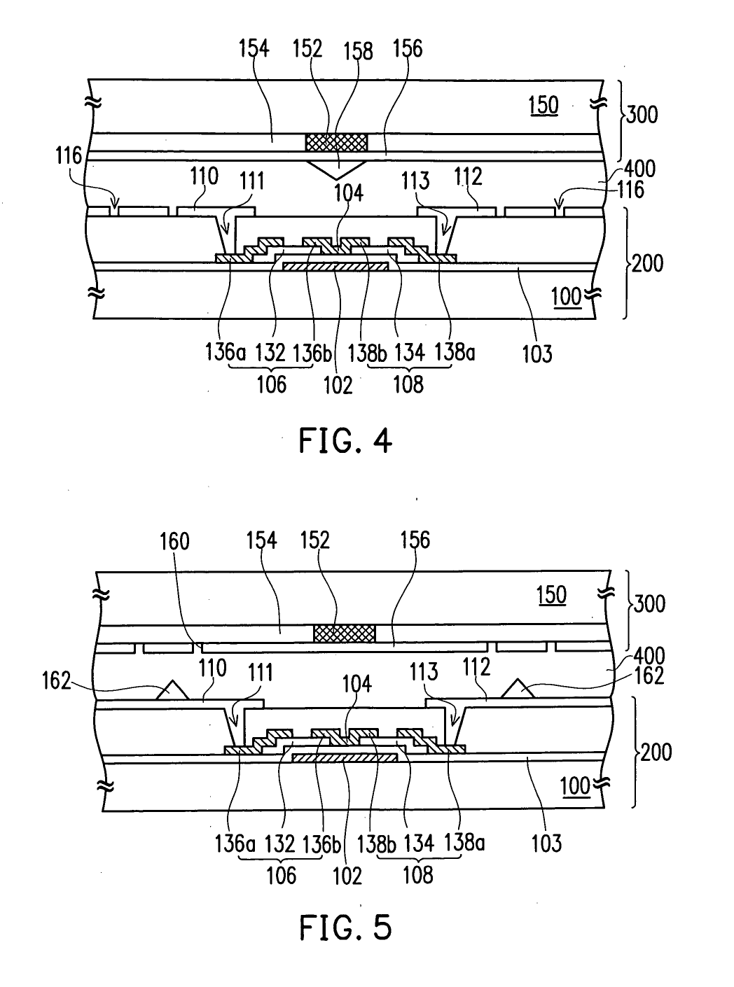

FIG. 4 is a cross-sectional schematic view of a liquid crystal display panel according to one preferred embodiment of the present invention. Referring to FIG. 4, the liquid crystal display panel of the present invention includes a thin film transistor array substrate 200; a color filter substrate 300; and a liquid crystal layer 400, disposed between the thin film transistor array substrate 200 and the color filter substrate 300. The thin film transistor array substrate 200 includes a plurality of pixel structures, which can be the pixel structures 10 or 20 as shown in FIG. 1 or FIG. 3. The pixel structure in FIG. 4 is described as the example of the pixel structure 20 in FIG. 3. Therefore, the structure shown in FIG. 4 is a wide-angle view liquid crystal display panel. If the pixel structure of the thin film transistor array substrate 200 is as the pixel structure 10 shown in FIG. 1, that is, no alignment protrusion/slit pattern are disposed in the liquid crystal display panel, the liquid crystal display panel is, for example, a twisted nematic liquid crystal display panel.

Referring to FIG. 4, the pixel structure of the thin film transistor array substrate 200 includes a first and a second thin film transistor 106, 108 and a fist and a second pixel electrode 110, 112, wherein the first thin film transistor 106 includes a gate 102, a channel layer 132, a source 136b and a drain 136a, and the second thin film transistor 108 includes a gate 102, a channel layer 134, a source 138b and a drain 138a. The first pixel electrode 110 is electrically connected to the drain 136a through the contact window 111, and the second pixel electrode 112 is electrically connected to the drain 138 through the contact window 113. Moreover, an alignment slit pattern 116 is further formed in the first and the second pixel electrodes 110, 112.

In addition, the color filter substrate 300 includes a substrate 150; a black matrix 152 and a color filter layer 154, disposed on the substrate 150; and an electrode layer 156. The color filter layer 154 is composed of, for example, filter patterns of red, green, blue. The material of the black matrix 152 includes, for example, metal or black resin. The electrode layer 156 covers the surfaces of the black matrix 152 and the color filter layer 154, and an electrical field is formed between the electrode layer 156 and the pixel electrodes 110, 112 disposed on the thin film transistor array substrate 200 to make the liquid crystal molecules 400 turn so as to achieve the display objective. In one embodiment , the color filter substrate 300 further includes an alignment protrusion pattern 158, disposed on the electrode layer 156. In particular, the arrangement of the alignment protrusion pattern 158 may match the alignment slit pattern 116 to achieve the objective of multi-domain alignment. For example, if the arrangement format of the alignment slit pattern 116 is as shown in FIG.3; that is, the alignment slit pattern 116 is composed of a plurality of slits parallel to the scan line 102, the arrangement format of the alignment protrusion pattern 158 is configured corresponding to the positions of the data line 108 and the scan line 102, so as to form the structure of multi-domain horizontal alignment (MHA).

Of course, the present invention does not limit the arrangement format and figure of the protrusion pattern 158 and the slit pattern 116, so that the protrusion pattern 158 and the slit pattern 116 can also be the structure of MVA, or other various structures.

In addition, the present invention also does not limit that the alignment pattern disposed on the thin film transistor array substrate 200 be slit pattern, which can also be the alignment protrusion pattern as shown in FIG. 5. The liquid crystal display panel shown in FIG. 5 is similar to FIG. 4, and the difference is that the alignment protrusion pattern 162 is disposed on the first and the second pixel electrodes 110, 112. Moreover, an alignment slit pattern 160 is formed in the electrode layer 156 of the color filter substrate 300. Also, the arrangement format of the protrusion pattern 162 may match the alignment slit pattern 160 to form a multi-domain horizontal or vertical alignment structure.

In the liquid crystal display panel as described above, regardless of the twisted nematic liquid crystal display panel, MHA liquid crystal display panel or MVA liquid crystal display panel, each pixel structure disposed on the thin film transistor array substrate includes two thin film transistors and two pixel electrodes, and the two thin film transistors in a single pixel structure have different device width/length ratios, and the two transistors are electrically connected to the same data line and the same scan line. Therefore, when the pixel structure is driven by the data line and the scan line, the two thin film transistors have different device width/length ratios, so that the two pixel electrodes in the pixel structure have different pixel electrode voltages, and the liquid crystal molecules can have two different arrangements in a single pixel structure. Further, the problem of color shift can be resolved.

Moreover, as the pixel structure of the present invention uses only a data line, a scan line, and a capacitor electrode, there's no difference between the design of the driving circuit of the present invention and the design of the common pixel structures, therefore there is no need for the additional design of special driving circuit. And, as the single pixel structure uses only a data line, a scan line, and a capacitance electrode, the opening ratio may not be reduced substantially.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pixel structure, comprising:
a scan line and a data line;
a first thin film transistor, electrically connected to the scan line and the data line and has a first device width/length ratio;
a second thin film transistor, electrically connected to the scan line and the data line and has a second device width/length ratio;
a first pixel electrode, electrically connected to the first thin film transistor; and
a second pixel electrode, electrically connected to the second thin film transistor.

2. The pixel structure as claimed in claim 1, wherein the first device width/length ratio of the first thin film transistor is greater than the second device width/length ratio of the second thin film transistor.

3. The pixel structure as claimed in claim 1, wherein the first pixel electrode and the second pixel electrode further include an alignment slit pattern therein.

4. The pixel structure as claimed in claim 3, wherein the alignment slit pattern includes a plurality of slits parallel to the scan line.

5. The pixel structure as claimed in claim 1, further including an alignment protrusion pattern, disposed on the first pixel electrode and the second pixel electrode.

6. The pixel structure as claimed in claim 1, further including a storage capacitor, disposed under the first pixel electrode and the second pixel electrode.

7. The pixel structure as claimed in claim 1, wherein the first pixel electrode and the second pixel electrode are transparent electrodes, reflective electrodes, or one is a reflective electrode and the other is a transparent electrode.

8. A liquid crystal display panel, comprising:
a thin film transistor array substrate, having a plurality of pixel structures, each pixel structure including:
a scan line and a data line;
a first thin film transistor, electrically connected to the scan line and the data line and having a first device width/length ratio;
a second thin film transistor, electrically connected to the scan line and the data line and having a second device width/length ratio;
a first pixel electrode, electrically connected to the first thin film transistor; and
a second pixel electrode, electrically connected to the second thin film transistor;
a color filter substrate, disposed opposite to the thin film transistor array substrate; and
a liquid crystal layer, disposed between the thin film transistor array substrate and the color filter substrate.

9. The liquid crystal display panel as claimed in claim 8, wherein the first device width/length ratio of the first thin film transistor of each pixel structure is greater than the second device width/length ratio of the second thin film transistor.

10. The liquid crystal display panel as claimed in claim 8, wherein the first pixel electrode and the second pixel electrode of each pixel structure further include an alignment slit pattern therein.

11. The liquid crystal display panel as claimed in claim 10, further including an alignment protrusion pattern disposed on the color filter array substrate.

12. The liquid crystal display panel as claimed in claim 10, wherein the alignment slit pattern includes a plurality of slits parallel to the scan line.

13. The liquid crystal display panel as claimed in claim 8, wherein the thin film transistor array substrate further includes an alignment protrusion pattern, disposed on the first pixel electrode and the second pixel electrode.

14. The liquid crystal display panel as claimed in claim 13, further including an alignment slit pattern, disposed on the color filter array substrate.

15. The liquid crystal display panel as claimed in claim 8, wherein each pixel structure further includes a storage capacitor, disposed under the first pixel electrode and the second pixel electrode.

16. The liquid crystal display panel as claimed in claim 8, wherein the first pixel electrode and the second pixel electrode of each pixel structure are transparent electrodes, reflective electrodes, or one is a reflective electrode and the other is a transparent electrode.

17. The liquid crystal display panel as claimed in claim 8, wherein the color filter array substrate includes a black matrix and a color filter layer.
